(19) United States
(12) Patent Application Publication
(10) Pub. No.: US 2024/0373581 A1
(43) Pub. Date: Nov. 7, 2024

(54) SERVER

(71) Applicant: XI'AN YEP TELECOM TECHNOLOGY CO., LTD., Shaanxi (CN)

(72) Inventor: JINLIANG LI, Shaanxi (CN)

(21) Appl. No.: 18/288,670

(22) PCT Filed: Nov. 3, 2021
(86) PCT No.: PCT/CN2021/128511

§ 371 Date: Oct. 27, 2023

(30) Foreign Application Priority Data
Apr. 28, 2021 (CN) 202110468061.0

(51) Int. Cl. H05K 7/14; G06F 1/18

(52) U.S. Cl. CPC H05K 7/1489; G06F 1/187

(57) ABSTRACT

A server includes a hard disk carrier, a wire arranging frame, and a cabinet having an accommodating space accommodating the hard disk carrier and the wire arranging frame. The hard disk carrier drives the wire arranging frame to be unfolded or folded in a length direction of the cabinet or in a thickness direction of the cabinet. The wire arranging frame includes a wire arranging frame body and a support member. The wire arranging frame body includes wire arranging arms hinged in sequence, and axes of rotation shafts between every two adjacent wire arranging arms are parallel to each other. The wire arranging arms include articulated arms located at a head end and a tail end of the wire arranging frame body and rotatably connected to the hard disk carrier and the cabinet. The support member is supported between the wire arranging arms and the bottom wall of the cabinet.

### CROSS REFERENCE TO RELATED APPLICATIONS AND CLAIM OF PRIORITY

This application claims benefit under 35 U.S.C. 119, 120, 121, or 365 (c), and is a National Stage entry from International Application No. PCT/CN2021/128511 filed on Nov. 3, 2021, which claims priority to the benefit of Chinese Patent Application No. 202110468061.0 filed in the Chinese Intellectual Property Office on Apr. 28, 2021, the entire contents of which are incorporated herein by reference.

### BACKGROUND

### 1. Technical Field

The present application relates to the technical field of servers, and particularly relates to a server.

### 2. Background Art

High-density storage servers are widely applied in this big data era, and how to deploy more hard disks in the same volume of space has become a technical problem of close attention among big data centers. A general form of server currently adopted in big data centers is chassis server, in which a slidable hard disk carrier carrying a great number of hard disks is configured in a cabinet of the chassis server to collaboratively execute a big data operation project at a cloud. The hard disks carried on the hard disk carrier require a large number of wires for data interaction with the outside, and these wires are typically accommodated by a wire arranging frame which can be driven to fold or unfold through pulling or pushing the hard disk carrier.

A wire arranging frame in the existing art includes a plurality of wire arranging arms hinged with each other. The plurality of wire arranging arms are mainly arranged in two modes: a first mode in which the wire arranging frame is stacked in a direction consistent with a length direction of the cabinet, and the wire arranging arms at two ends in the length direction of the cabinet are respectively hinged with the hard disk carrier and the cabinet of the server: and a second mode in which the wire arranging frame is stacked in a direction consistent with a thickness direction of the cabinet, and the wire arranging arms at two ends in the thickness direction of the cabinet are respectively hinged with the hard disk carrier and the cabinet of the server.

However, in the first mode, the wire arranging frame may occupy more layout space for the hard disks, resulting in a reduced number of hard disks on the hard disk carrier: while in the second mode, the wire arranging frame tends to be deformed during unfolding, thereby interfering with unfolding or folding of the wire arranging frame.

### SUMMARY

The present application provides a server which can prevent deformation of the wire arranging frame while ensuring that the wire arranging frame occupies a smaller space.

The present application provides a server, including a cabinet, a hard disk carrier, and a wire arranging frame, wherein an accommodating space for accommodating the hard disk carrier and the wire arranging frame is formed in the cabinet, and the hard disk carrier drives the wire arranging frame to be unfolded in a length direction of the cabinet or to be folded in a thickness direction of the cabinet: the wire arranging frame includes a wire arranging frame body and a support member: the wire arranging frame body includes a plurality of wire arranging arms hinged in sequence, and axes of rotation shafts between every two adjacent wire arranging arms are parallel to each other: the plurality of wire arranging arms include two articulated arms which are located at a head end and a tail end of the wire arranging frame body respectively and rotatably connected to the hard disk carrier and the cabinet respectively: and the support member is supported between the wire arranging arms and the bottom wall of the machine cabinet.

Optionally, in the server provided by the present application, a first end of the support member extends toward the wire arranging arms, and a second end of the support member extends toward the bottom wall of the cabinet.

Optionally, in the server provided by the present application, the first end of the support member is connected to a middle portion of the wire arranging frame body, and the second end of the support member is supported against the bottom wall of the cabinet.

Optionally, in the server provided by the present application, the plurality of wire arranging arms further include a connecting arm connected between the two articulated arms, and the support member is supported between the articulated arms and the bottom wall of the cabinet, or between the connecting arm and the bottom wall of the cabinet.

Optionally, in the server provided by the present application, a plurality of support members are provided, including a plurality of first support members which are respectively disposed on the wire arranging arms on two sides of the middle portion of the wire arranging frame body, and arranged symmetrically with respect to the middle portion of the wire arranging frame body.

Optionally, in the server provided by the present application, the plurality of support members further include a plurality of second support members; and a first end of each second support member is connected to an end of a corresponding wire arranging arm.

Optionally, in the server provided by the present application, the second end of the support member is provided with a sliding guide that is slidably fitted with the bottom wall of the cabinet.

Optionally, in the server provided by the present application, support members on different wire arranging arms have different extension lengths.

Optionally, in the server provided by the present application, each wire arranging arm is provided with a wire accommodating groove which has an extending direction consistent with the wire arranging arm where the wire accommodating groove is located.

Optionally, in the server provided by the present application, wire accommodating grooves of two adjacent wire arranging arms are opened to opposite directions.

The server provided by the present application includes a cabinet, a hard disk carrier, and a wire arranging frame, where an accommodating space for accommodating the hard disk carrier and the wire arranging frame is formed in the cabinet, and the hard disk carrier drives the wire arranging frame to be unfolded in a length direction of the cabinet or to be folded in a thickness direction of the cabinet: the wire arranging frame includes a wire arranging frame body and a support member: the wire arranging frame body includes a plurality of wire arranging arms hinged in sequence, and axes of rotation shafts between every two adjacent wire arranging arms are parallel to each other: the plurality of wire arranging arms include two articulated arms which are located at a head end and a tail end of the wire arranging frame body respectively and rotatably connected to the hard disk carrier and the cabinet respectively: and the support member is supported between the wire arranging arms and the bottom wall of the machine cabinet. The wire arranging frame in the server of the present application not only occupies a smaller space, but also is not easily deformed.

The construction and other application objects and beneficial effects of the present application will become more apparent from the description of the exemplary embodiments in conjunction with the accompanying drawings.

### BRIEF DESCRIPTION OF THE DRAWINGS

To illustrate the technical solutions in the embodiments of the present application or the existing art more clearly, the drawings to be used in description of the embodiments or the existing art will be briefly described below. Apparently, the drawings in the following description are merely some embodiments of the present application, and other drawings may be derived from these drawings by those of ordinary skill in the art without any creative labor.

FIG. 1 is a schematic perspective view of a server according to an embodiment of the present application:

FIG. 2A is a schematic diagram showing an internal structure of a server according to an embodiment of the present application with a wire arranging frame in a folded state:

FIG. 2B is an enlarged partial view of the structure at A in FIG. 2A:

FIG. 3 is a schematic diagram showing an internal structure of a server according to an embodiment of the present application with a wire arranging frame in an unfolded state:

FIG. 4A is a schematic structural diagram of a wire arranging frame in a folded state in a server according to an embodiment of the present application: and

FIG. 4B is a schematic structural diagram of a wire arranging frame in an unfolded state in a server according to an embodiment of the present application.

### DETAIL DESCRIPTION

To make the objects, technical solutions and advantages of the embodiments of the present application clearer, the technical solutions provided in the embodiments of the present application will be described clearly and completely below with reference to the accompanying drawings in the embodiments of the present application. Apparently, the described embodiments are part, but not all, of the embodiments of the present application.

All other embodiments obtained by a person of ordinary skill in the art based on the embodiments in the present application without any creative labor belong to the protection scope of the present application. The embodiments described below and features thereof may be combined with each other without conflict.

In the description of the present application, it is to be understood that the terms “central,” “longitudinal,” “lateral,” “length,” “width,” “thickness,” “upper,” “lower,” “front,” “rear,” “left,” “right,” “vertical,” “horizontal,” “top,” “bottom,” “inner,” “outer,” “clockwise,” “counterclockwise,” “axial,” “radial,” “circumferential,” and the like indicate an orientation or positional relationship based on the orientation or positional relationship shown in the drawings, and are merely used for facilitating and simplifying the description, instead of indicating or implying that the referred device or element is necessarily in a specific orientation, or constructed and operated in the specific orientation, and therefore, they should not be construed as limitations to the present application.

In this application, unless expressly stated or limited otherwise, the terms “mounted,” “connected,” “secured,” and the like are to be construed broadly and encompass, for example, both fixed and removable connection, or integral connection: or a direct connection, an indirect connection via an intermedium, or internal communication or interaction between two elements. The specific meaning of the above terms in the present application may be understood by those of ordinary skill in the art as the case may be.

It should be noted that, in the description of the present application, the terms “first” and “second” are used merely for convenience of describing different components, and are not to be construed as indicating or implying a sequential relationship, relative importance or implicitly indicating the number of technical features indicated. Therefore, a feature defined by “first” or “second” may include at least one that feature either explicitly or implicitly.

High-density storage servers are widely applied in this big data era, and how to deploy more hard disks in the same volume of space has become a technical problem of close attention among big data centers. A general form of server currently adopted in big data centers is chassis server, in which a server cabinet is used for assembling and installing panels, inserts, a subrack, electronic components, devices, mechanical parts and components to form an integral installation box. A slidable hard disk carrier carrying a great number of hard disks is configured in the cabinet to collaboratively execute a big data operation project at a cloud. The hard disks carried on the hard disk carrier require a large number of wires for data interaction with the outside, and these wires are typically accommodated by a wire arranging frame which can be driven to fold or unfold through pulling or pushing the hard disk carrier.

In the existing art, the wire arranging frame includes a plurality of wire arranging arms hinged with each other. The plurality of wire arranging arms are mainly arranged in two modes: a first mode in which the wire arranging frame is stacked in a direction consistent with a length direction of the cabinet, and the wire arranging arms at two ends in the length direction of the cabinet are respectively hinged with the hard disk carrier and the cabinet of the server: and a second mode in which the wire arranging frame is stacked in a direction consistent with a thickness direction of the cabinet, and the wire arranging arms at two ends in the thickness direction of the cabinet are respectively hinged with the hard disk carrier and the cabinet of the server.

However, in the first mode, the wire arranging frame may occupy more layout space for the hard disks, resulting in a reduced number of hard disks on the hard disk carrier: while in the second mode, the wire arranging frame tends to be deformed during unfolding, thereby interfering with unfolding or folding of the wire arranging frame.

Therefore, the present application provides a server in which the wire arranging frame can be folded in a thickness direction of the cabinet, and a support member is disposed between the wire arranging frame and the cabinet, so that deformation of the wire arranging frame is prevented while ensuring that the wire arranging frame occupies a smaller space, thereby avoiding interference with movement of the wire arranging frame due to collisions with the cabinet.

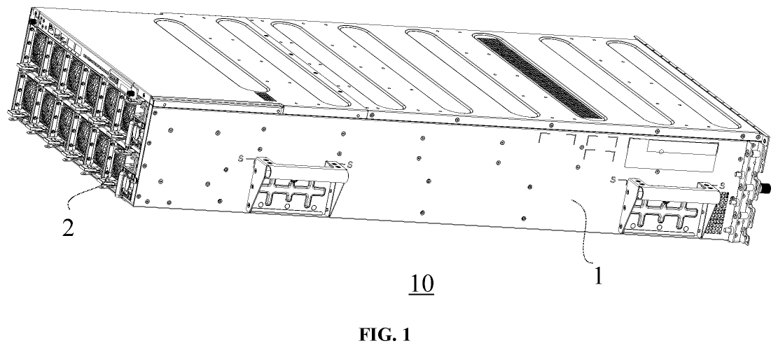

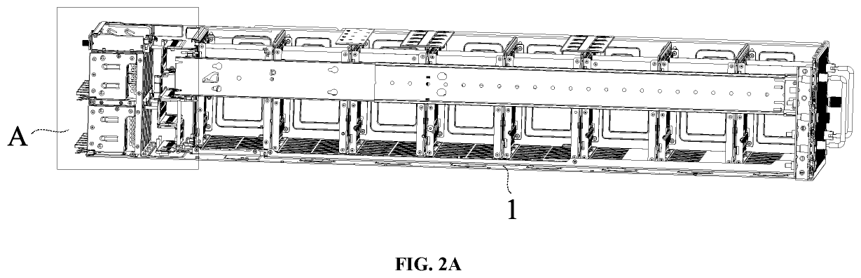

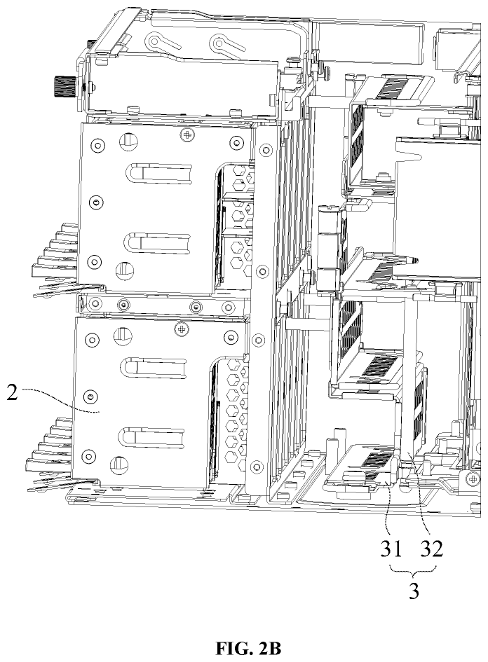

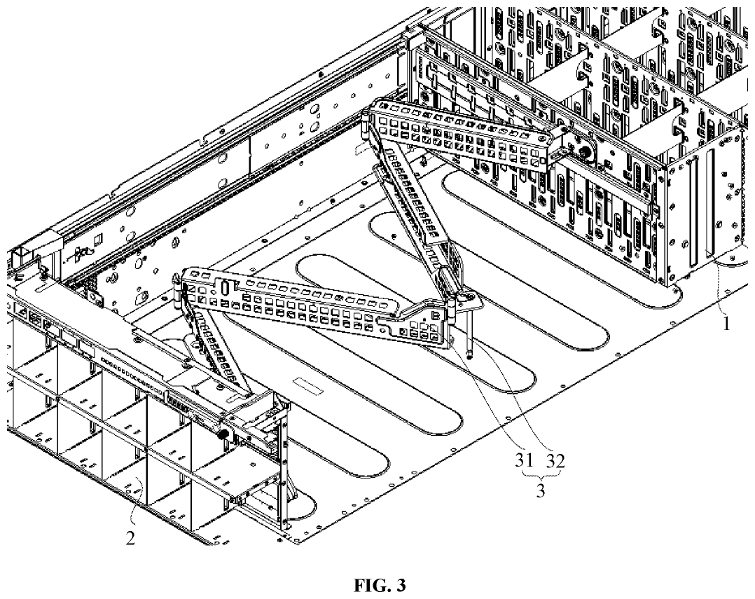

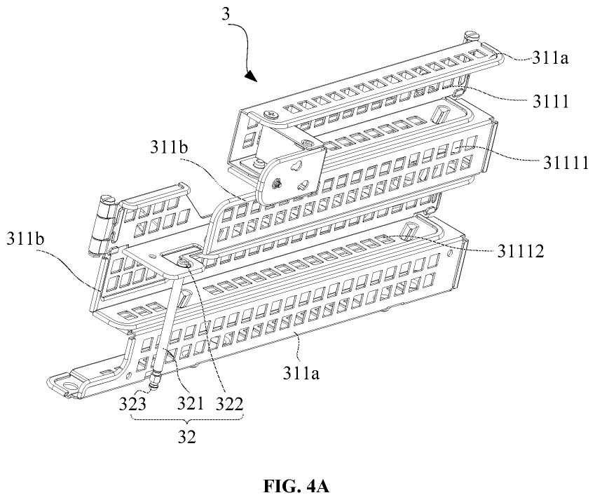

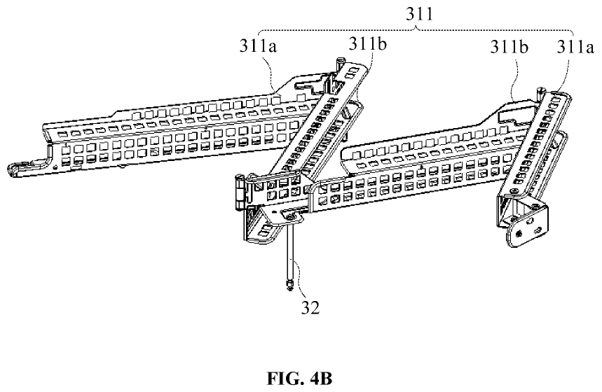

FIG. 1 is a schematic perspective view of a server according to an embodiment of the present application. FIG. 2A is a schematic diagram showing an internal structure of a server according to an embodiment of the present application with a wire arranging frame in a folded state. FIG. 2B is an enlarged partial view of the structure at A in FIG. 2A. FIG. 3 is a schematic diagram showing an internal structure of a server according to an embodiment of the present application with a wire arranging frame in an unfolded state. FIG. 4A is a schematic structural diagram of a wire arranging frame in a folded state in a server according to an embodiment of the present application. FIG. 4B is a schematic structural diagram of a wire arranging frame in an unfolded state in a server according to an embodiment of the present application.

As shown in FIGS. 1 to 4B, an embodiment of the present application provides a server 10, including a cabinet 1, a hard disk carrier 2, and a wire arranging frame 3. An accommodating space for accommodating the hard disk carrier 2 and the wire arranging frame 3 is formed in the cabinet 1. The hard disk carrier 2 is configured to carry a hard disk assembly, and drives the wire arranging frame 3 to be unfolded in a length direction of the cabinet 1 or to be folded in a thickness direction of the cabinet 1. The wire arranging frame 3 includes a wire arranging frame body 31 and a support member 32. The wire arranging frame body 31 includes a plurality of wire arranging arms 311 hinged in sequence, and axes of rotation shafts between every two adjacent wire arranging arms 311 are parallel to each other. The plurality of wire arranging arms 311 include two articulated arms 311a which are located at a head end and a tail end of the wire arranging frame body 31 respectively and rotatably connected to the hard disk carrier 2 and the cabinet 1 respectively. The support member 32 is supported between the wire arranging arms 311 and a bottom wall of the cabinet 1. The rotation shaft between two adjacent wire arranging arms 311 may be a pin, a screw, or the like. The specific type of the rotation shaft is not limited herein.

It should be noted that in order to prevent a length of the folded wire arranging frame 3 in the thickness direction of the cabinet 1 from being greater than a length of the hard disk carrier 2 in that direction and making the wire arranging frame 3 difficult to fold, in some embodiments, the length of the folded wire arranging frame 3 in the thickness direction of the cabinet 1 is less than or equal to the length of the hard disk carrier 2 in that direction.

Further, in order to ensure that the hard disk carrier 2 drives the wire arranging frame 3 to be unfolded in the length direction of the cabinet 1, in this embodiment, a connection point between one articulated arm 311a and the hard disk carrier 2, and a connection point between the other articulated arm 311a and the cabinet 1, are located on a diagonal line of a base plate 11, whereby a push-pull direction of the hard disk carrier 2 is limited.

In a specific implementation of the present embodiment, a base plate 11 is provided on the bottom wall of the cabinet 1, and the support member 32 is supported between the wire arranging arm 311 and the base plate 11.

In some embodiments, the support member 32 and the wire arranging arm 311 may be detachably or fixedly connected. The specific connection mode between the support member 32 and the wire arranging arm 311 is not limited herein.

In the server 10 provided in the embodiment of the present application, the hard disk carrier 2 can drive the wire arranging frame 3 to be unfolded in the length direction of the cabinet 1 or to be folded in the thickness direction of the cabinet 1, and the wire arranging frame 3 includes the wire arranging frame body 31 and the support member 32, and the support member 32 is supported between the wire arranging arms 311 and the bottom wall of the cabinet 1, so that the wire arranging frame 3 occupies a smaller space in the cabinet 1, and the support member 32 can support the wire arranging arm 311 so that in the unfolding process of the wire arranging frame 3, the wire arranging frame body 31 is prevented from approaching the bottom wall of the cabinet 1 due to the gravity of the cable and causing deformation of the wire arranging frame body 31 and collisions with the bottom wall of the cabinet 1, thereby avoiding interference with movement of the wire arranging frame body 31. Therefore, the wire arranging frame 3 in the server 10 provided by the embodiment of the present application occupies a smaller space, is not easy to deform, and can move smoothly.

In addition, it should be further noted that the hard disk carrier 2 drives the wire arranging frame 3 to be folded in the thickness direction of the cabinet 1, which, compared with the case where hard disk carrier 2 drives the wire arranging frame 3 to be folded in the length direction of the cabinet 1, can increase a pull-out stroke of the hard disk carrier 2, and save the hard disk space.

It should be noted that the hard disk carrier 2 may be a hard disk cage, and the wire arranging frame 3 may be made of a metal material, such as aluminum or stainless steel. The specific form of the hard disk carrier 2 and the specific material of the wire arranging frame 3 are not limited herein.

In order to accommodate cables, each wire arranging arm 311 is provided with a wire accommodating groove 3111 which has an extending direction consistent with the wire arranging arm 311 where the wire accommodating groove 3111 is located. The wire accommodating groove 3111 is configured to accommodate a cable, which may be a cable for transmitting signals.

In some alternative implementations, wire accommodating grooves 3111 of two adjacent wire arranging arms 311 are opened to opposite directions, so that the cables in the wire accommodating grooves 3111 will not contact or press each other while the wire arranging frame 3 is unfolded or folded.

In order for effective heat dissipation and fixation of the cable, in some embodiments, first vias 31111 distributed at intervals are provided on a bottom wall of the wire accommodating groove 3111, second vias 31112 distributed at intervals are provided on a sidewall of the wire accommodating groove 3111, an axial direction of the first vias 31111 is consistent with a thickness direction of the bottom wall of the wire accommodating groove 3111, and an axial direction of the second vias 31112 is consistent with a thickness direction of the sidewall of the wire accommodating groove 3111. By providing the first vias 31111 and the second vias 31112, heat dissipation of the cable can be facilitated, and the cable can be fixed in the wire accommodating groove 3111 with a binder through one of the first vias 31111.

Specifically, one end of the cable is electrically connected to a mainboard of the server, and the other end is electrically connected to the hard disk assembly.

In order to offset the gravity generated by the cable with a support force of the support member 32 to the wire arranging arm 311, a first end of the support member 32 extends towards the wire arranging arm 311, and a second end of the support member 32 extends towards the bottom wall of the cabinet 1, so that the support member 32 generates a support force on the wire arranging arm 311 in a direction parallel to the gravity direction of the cable, and thus the wire arranging arm 311 is prevented from being deformed under the gravity of the cable.

It should be further noted that the extending direction of the support member 32 is perpendicular to the push-pull direction of the hard disk carrier 2.

In order for a uniform stress over the wire arranging frame body 31, in this embodiment, the first end of the support member 32 is connected to a middle portion of the wire arranging frame body 31, and the second end of the support member 32 is supported against the bottom wall of the cabinet 1. It should be noted that the “middle portion of the wire arranging frame body 31” here may be interpreted as a geometric center of the wire arranging frame body 31.

As shown in FIGS. 4A and 4B, the plurality of wire arranging arms 311 further include a connecting arm 311b connected between the two articulated arms 311a, and the support member 32 is supported between the articulated arms 311a and the bottom wall of the cabinet 1, or between the connecting arm 311b and the bottom wall of the cabinet 1.

In a specific implementation of the present embodiment, the plurality of wire arranging arms 311 include two connecting arms 311b connected between the two articulated arms 311a, and the support member 32 is supported between the connecting arms 311b and the bottom wall of the cabinet 1.

In order to further prevent deformation of the wire arranging frame body 31, in some alternative implementations, a plurality of support members 32 are provided, including a plurality of first support members which are respectively disposed on the wire arranging arms 311 on two sides of the middle portion of the wire arranging frame body 31, and arranged symmetrically with respect to the middle portion of the wire arranging frame body 31. In this manner, the plurality of support members 32 offer a greater support force to the wire arranging frame body 31 while ensuring a uniform stress over the wire arranging frame body 31, thereby further preventing deformation of the wire arranging frame body 31.

Further, the plurality of support members 32 further include a plurality of second support members: and a first end of each second support member is connected to an end of a corresponding wire arranging arm 311. In this manner, under a collaborative action of the first support members and the second support members, it is ensured that the wire arranging arms 311 have a plurality of bearing points with the support member 32, and the wire arranging arms 311 can be folded and unfolded normally while the stress over the wire arranging arms 311 is uniform.

To facilitate folding and unfolding of the wire arranging frame 3, in some alternative implementations, the second end of the support member 32 is provided with a sliding guide that is slidably fitted with the base plate 11. Thereby, more smooth folding and unfolding of the wire arranging frame 3 is guaranteed.

In a specific implementation of the present embodiment, the support member 32 includes a base rod part 321, and a first support part 322 and a second support part 323 detachably connected to two ends of the base rod part 321. The first support part 322 is supported against and detachably connected to the wire arranging arm 311, while the second support part 323 is supported against the base plate 11. The first support part 322 and the base rod part 321, the first support part 322 and the wire arranging arm 311, and the second support part 323 and the base rod part 321 may be connected via threaded connection, respectively. The specific structure of the support member 32, the connection manner between internal structures of the support member 32, and the connection manner between the support member 32 and the wire arranging arm 311 are not particularly limited herein.

In an embodiment of the present application, since the wire arranging frame body 31 includes a plurality of wire arranging arms 311 hinged in sequence, and the plurality of wire arranging arms 311 can be folded in the thickness direction of the cabinet 1, in this embodiment, support members 32 on different wire arranging arms 311 have different extension lengths so that each wire arranging arm 311 is effectively supported by the corresponding support member 32. In this manner, each support member 32 can be supported between the corresponding wire arranging arm 311 and the base plate 11, so that the wire arranging frame body 31 is effectively supported and prevented from being deformed.

Specifically, when the hard disk carrier 2 is pulled, the articulated arm 311a

connected to the hard disk carrier is driven to extend, and then the connecting arm 311b and the other articulated arm 311a are driven to extend. When the hard disk carrier 2 is pushed, the articulated arm 311a connected to the hard disk carrier is driven to contract, and then the connecting arm 311b and the other articulated arm 311a are driven to contract, so that the wire arranging frame 3 is folded in the thickness direction of the cabinet 1. It should be noted that during the folding and unfolding of the wire arranging frame 3, the support member 32 will slide relative to the base plate 11 along with the corresponding wire arranging arm 311.

The server provided by the present application includes a cabinet, a hard disk carrier, and a wire arranging frame, where an accommodating space for accommodating the hard disk carrier and the wire arranging frame is formed in the cabinet, and the hard disk carrier drives the wire arranging frame to be unfolded in a length direction of the cabinet or to be folded in a thickness direction of the cabinet: the wire arranging frame includes a wire arranging frame body and a support member: the wire arranging frame body includes a plurality of wire arranging arms hinged in sequence, and axes of rotation shafts between every two adjacent wire arranging arms are parallel to each other; the plurality of wire arranging arms include two articulated arms which are located at a head end and a tail end of the wire arranging frame body respectively and rotatably connected to the hard disk carrier and the cabinet respectively; and the support member is supported between the wire arranging arms and the bottom wall of the machine cabinet. The wire arranging frame in the server of the present application not only occupies a smaller space, but also is not easily deformed.

Finally, it should be noted that: the above embodiments are only used to illustrate the technical solutions of the present application, and not to limit the present application; although the present application has been described in detail with reference to the foregoing embodiments, those of ordinary skill in the art will understand that: the technical solutions described in the foregoing embodiments may still be modified, or some or all of the technical features therein may be equivalently replaced; and these modifications or substitutions do not make the corresponding technical solution essentially depart from the scope of the technical solutions of the embodiments of the present application.

1. A server comprising:
a cabinet;
a hard disk carrier; and
a wire arranging frame,
wherein an accommodating space for accommodating the hard disk carrier and the wire arranging frame is formed in the cabinet, and the hard disk carrier drives the wire arranging frame to be unfolded in a length direction of the cabinet or to be folded in a thickness direction of the cabinet;
the wire arranging frame includes a wire arranging frame body and a support member;
the wire arranging frame body includes a plurality of wire arranging arms hinged in sequence, and axes of rotation shafts between every two adjacent wire arranging arms are parallel to each other;
the plurality of wire arranging arms include two articulated arms which are located at a head end and a tail end of the wire arranging frame body respectively and rotatably connected to the hard disk carrier and the cabinet respectively; and
the support member is supported between the wire arranging arms and a bottom wall of the cabinet.

2. The server of claim 1, wherein a first end of the support member extends toward the wire arranging arms, and a second end of the support member extends toward the bottom wall of the cabinet.

3. The server of claim 2, wherein the first end of the support member is connected to a middle portion of the wire arranging frame body, and the second end of the support member is supported against the bottom wall of the cabinet.

4. The server of claim 1, wherein the plurality of wire arranging arms further include a connecting arm connected between the two articulated arms, and the support member is supported between the articulated arms and the bottom wall of the cabinet, or between the connecting arm and the bottom wall of the cabinet.

5. The server of claim 4, wherein a plurality of support members are provided, including a plurality of first support members which are respectively disposed on the wire arranging arms on two sides of the middle portion of the wire arranging frame body, and arranged symmetrically in pairs with respect to the middle portion of the wire arranging frame body.

6. The server of claim 5, wherein the plurality of support members further include a plurality of second support members; and
a first end of each second support member is connected to an end of a corresponding wire arranging arm.

7. The server of claim 6, wherein the second end of the support member is provided with a sliding guide that is slidably fitted with the bottom wall of the cabinet.

8. The server of claim 5, wherein support members on different wire arranging arms have different extension lengths.

9. The server of claim 8, wherein each wire arranging arm is provided with a wire accommodating groove which has an extending direction consistent with the wire arranging arm where the wire accommodating groove is located.

10. The server of claim 9, wherein wire accommodating grooves of two adjacent wire arranging arms are opened to opposite directions.
